(19) United States
(12) Patent Application Publication
(10) Pub. No.: US 2005/0082605 A1
(43) Pub. Date: Apr. 21, 2005

(54) Semiconductor device and method for manufacturing semiconductor device

(75) Inventor: Yasushi Akasaka, Ibaraki (JP)

Correspondence Address: LEYDIG VOIT & MAYER, LTD, 700 THIRTEENTH ST. NW, SUITE 300, WASHINGTON, DC, 20005-3960, US

(73) Assignee: Semiconductor Leading Edge Technologies, Inc., Tsukuba-shi (JP)

(21) Appl. No.: 10/962,707

(22) Filed: Oct. 13, 2004

(30) Foreign Application Priority Data
Oct. 17, 2003 (JP) 2003-358092

(51) Int. Cl. H01L 29/76

(52) U.S. Cl. 257/329

(57) ABSTRACT

A gate insulating film is formed in a first region and a second region of a substrate, a first metallic film is formed on the gate insulating film in one of the first region or the second region, and a second metallic film is formed on each of the first and second regions. Furthermore, a protective film is formed on the second metallic film, and the protective film and the metallic film are patterned to the pattern of the gate electrode. Next, a first sidewall is formed on the side of a gate electrode. Then, impurities producing first and second conductivity types are implanted into the surface of the substrate in respective regions, using the first sidewalls and the gate electrodes as masks to form a first impurity-diffused region, and impurities producing second and first conductivity types are implanted to form an impurity diffusion preventing layer. Thereafter, a second sidewall is formed on the side of the first sidewall, and an impurity is implanted into the surface of the substrate using the second sidewalls and the gate electrodes as masks to form a second impurity-diffused region.

### BACKGROUND OF THE INVENTION

1. Field of the Invention

The present invention relates to a semiconductor device and a method for manufacturing a semiconductor device. More specifically, the present invention relates to a semiconductor device including field-effect transistors, and a method for manufacturing such a semiconductor device.

2. Background Art

In recent years, with the high integration and miniaturization of semiconductor devices, transistors have also been rapidly miniaturized. Concurrent therewith, the thickness of gate insulating films of transistors has been reduced to an EOT (equivalent oxide thickness) of about 2.0 nm or less. When the thickness of gate insulating films is so reduced, the leakage current of the conventional gate insulating films composed of SiO₂ increases to the value not negligible. Therefore, a high-dielectric-constant film (hereafter abbreviated as high-k film) is used as the gate insulating film. When a high-k film is used as the gate insulating film, the EOT can be thinned, and power consumption can be reduced while securing the actual physical thickness of the film to be thick, and suppressing the tunnel current.

On the other hand, in gate electrodes, the lowering of capacitance due to depletion of the electrode causes problems with the miniaturization of transistors. In the case of conventional gate electrodes composed of polysilicon, since the lowering of capacitance converted to the thickness of a silicon oxide film corresponds to increase in film thickness of about 0.5 nm, it cannot be neglected when compared with the film thickness of the gate. Therefore, in the gate electrode, the use of metals in place of conventional polysilicon is considered. When the metal gate is used, the above-described depletion problems can be reduced.

However, in the conventional gate electrode using a polysilicon film, a p⁺ region and an n⁺ region, namely regions having two types of work functions, can be separately formed using a photolithography method and an ion implantation method. When a CMOSFET (complementary metal oxide semiconductor field effect transistor), for example, using a polysilicon film as the gate electrode is formed, a method for obtaining a low threshold voltage by using n⁺-poly-Si for the gate electrode of the n-MOSFET and p⁺-poly-Si for the gate electrode of the p-MOSFET (dual work function), is widely used.

However, in general, for metal gates, methods equivalent to the method using polysilicon gate that can easily vary work functions by depositing a film, and then implanting each type of impurity to respective regions, have not been established.

Therefore, when metal gates are used, different metallic films must be formed in the p-MISFET side and n-MISFET side as gate electrodes. Specifically when a CMOS is formed using a metal gate, it is formed in the following manners.

First, an n-well and a p-well are formed in the regions for forming a p-MIS and an n-MIS divided by the isolating region, respectively. Thereafter, a gate insulating film, for example a high-k film such as an HfO₂ film, is formed in each region. Thereafter, a metallic film, such as a TiN film, is deposited on the gate insulating film, and then the TiN film in the n-MIS side is selectively removed. Thereafter, a metallic film such as a TaSiN film and a polysilicon film are deposited on the entire surface. Thereafter, the laminated film deposited in each of the p-MIS and n-MIS regions is processed into the shape of the gate electrode. Specifically, in the p-MIS region, a laminated film composed of a polysilicon film, a TaSiN film and a TiN film is etched to be a gate-electrode shape; and in the n-MIS region, a polysilicon film, and a TaSiN film to form a gate electrode in each region. Thereafter, ions are implanted into each region using each gate electrode as a mask by a normal method to form a source-drain region, and heat treatment for the activation of impurities is performed (e.g., refer to Document, Samavedam et al., Dual-Metal Gate CMOS with HfO₂ Gate Dielectric, IEDM Tech. Digest 2002, p443).

Here, by forming a polysilicon film as the uppermost layer of each gate electrode, the mixing of the impurities in the metallic films formed as the lower layers can be prevented during ion implantation. Therefore, according to this structure, the deterioration of the metal gate due to the mixing of impurities in the subsequent heat treatment step or the like can be prevented.

However, the gate having a polysilicon film formed on the top has a high resistance of the electrode, and causes RC delay. Therefore, the switching speed of the circuit cannot be increased.

In addition to the above-described method, in order to suppress the short-channel effect in a minute transistor, a halo may be formed outside the diffused layer using tilt ion implantation. In this case, the impurity is easily implanted into the side of the metal gate electrode, and if the impurity is implanted into the metal gate, the metal gate may be deteriorated in the subsequent steps resulting in the deterioration of the semiconductor device.

Furthermore, in the case of a transistor having the above-described structure, since metals are exposed on the side of the gate electrode, the gate electrode may be simultaneously etched in the subsequent cleaning process or the like to cause problems.

### SUMMARY OF THE INVENTION

Therefore, the present invention solves the problems as described above, and provides a semiconductor device and a method for the manufacture thereof to avoid the depletion of the gate electrode even in the case where metals are used for the gate electrode, and at the same time, to suppress RC delay, and the deterioration, etching or the like of the gate electrode in subsequent steps, and to cope with miniaturization and the improvement of performance.

According to one aspect of the present invention, a semiconductor device comprises: a substrate, an isolating region dividing the substrate into a first region and a second region, a first transistor of a first conductivity type formed in the first region, and a second transistor of a second conductivity type formed in the second region. Each of the first transistor and the second transistor comprises: a gate insulating film formed on the substrate, a gate electrode composed of a metallic material formed on the gate insulating film, a protective film coating the surface of the gate electrode, a first sidewall coating at least the side of the gate electrode, first impurity-diffused layers formed apart from each other and on both sides of the first sidewall in the vicinity of the surface of the substrate, a second sidewall coating at least the outside of the first sidewall, and second impurity-diffused layers formed apart from each other and on both sides of the second sidewall in the vicinity of the surface of the substrate. The gate electrode of the first transistor has a laminated structure composed of several metals, and further has another metallic film on the lowermost layer of an electrode of the same structure as the structure of the second transistor.

According to another aspect of the present invention, in a method for manufacturing a semiconductor device, an isolating region is formed for dividing a substrate into a first region and a second region. A gate insulating film is formed in the first region and the second region. A first metallic film is formed on the gate insulating film of either one of the first region or the second region. A second metallic film is formed on each of the first region or the second region. A protective film is formed on the second metallic film of the first region and the second region. A gate electrode is patterned the protective film, the first metallic film and the second metallic film to form a gate electrode in each of the first region and the second region. A first sidewall is formed on each of gate electrodes in the first region and the second region. A first diffused layer is formed in each of the first and second regions by implanting ions of a first conductivity type into the first region using the gate electrode and the first sidewall as masks, and by implanting ions of a second conductivity type into the second region using the gate electrode and the first sidewall as masks. An impurity diffusion preventing layer including a junction interface of the first impurity-diffused layer is formed by implanting ions of the opposite conductivity type from the first conductivity type into the first region using the gate electrode and the first sidewall as masks, and by forming an impurity diffusion preventing layer including a junction interface of the first impurity-diffused layer, by implanting ions of the opposite conductivity type from the second conductivity type into the second region using the gate electrode and the first sidewall as masks. A second sidewall is formed on each side of the first sidewall. A second impurity-diffused layer is formed in each of the first and second regions by implanting ions of the first conductivity type into the first region using the gate electrode and the first and second sidewalls as masks, and by implanting ions of the second conductivity type into the second region using the gate electrode and the first and second sidewalls as masks.

Other and further objects, features and advantages of the invention will appear more fully from the following description.

### BRIEF DESCRIPTION OF THE DRAWINGS

FIG. 1 is a schematic sectional view for illustrating a semiconductor device 100 according to the first embodiment of the present invention;

FIG. 2 is a flow diagram for illustrating the method for manufacturing a semiconductor device 100 according to the first embodiment of the present invention;

FIGS. 3 to 12 are schematic sectional views for illustrating the states in each manufacturing step of the semiconductor device 100 according to the first embodiment of the present invention;

FIG. 13 is a schematic sectional view for illustrating a semiconductor device according to the second embodiment of the present invention.

### DETAILED DESCRIPTION OF THE PREFERRED EMBODIMENTS

Embodiments of the present invention will be described below referring to the drawings. In the drawings, the same or corresponding parts will be denoted by the same reference numerals, and the description thereof will be simplified or omitted.

First Embodiment

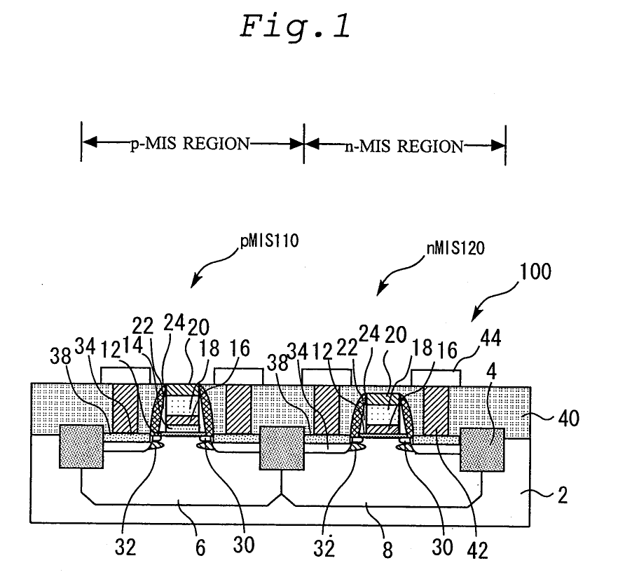

FIG. 1 is a schematic sectional view for illustrating a semiconductor device 100 according to the first embodiment of the present invention.

As FIG. 1 illustrates, a p-type MISFET (metal insulator semiconductor field effect transistor) 110 and an n-type MISFET 120 are formed in the semiconductor device 100. In this specification, the p-type MISFET 110 is referred to as the p-MIS 110, and the n-type MISFET 120 is referred to as the n-MIS 120 for simplifying description. The region for forming the p-MIS 110 and the region for forming the n-MIS 110 are referred to as the p-MIS region and the n-MIS region, respectively.

An isolating region 4 is formed on a silicon substrate 2, and the isolating region 4 divides the silicon substrate 2 into a p-MIS region and an n-MIS region. An n-well 6 and a p-well 8 are formed in the p-MIS region and the n-MIS region, respectively. In each region, an HfO₂ film 12 is formed as a gate insulating film. The HfO₂ film 12 is a high-dielectric-constant film (hereafter referred to as high-k film) having a much higher specific dielectric constant than a silicon oxide film. The EOT (equivalent silicon oxide film thickness) of the HfO₂ film 12 is about 2.0 nm.

In the p-MIS region, an Ni film 14 is formed on the HfO₂ film 12. The thickness of the Ni film 14 is about 5.0 to 10.0 nm. A Ti film 16 is formed on each of the Ni film 14 of the p-MIS region and the HfO₂ film 12 of the n-MIS region. The thickness of the Ti film 16 is about 5.0 to 10.0 nm. A W film 18 is formed on the Ti film 16 in each region. The thickness of the W film 18 is about 40 to 50 nm. A cap film 20 is formed on the W film 18 in each region. Here, the cap film 20 is a thin film composed of SiN. In the p-MIS region, the gate electrode is a laminated structure composed of the Ni film 14, Ti film 16, and the W film 18; and in the n-MIS region, the gate electrode is a laminated structure composed of the Ti film 16 and the W film 18. The cap film 20 protects the upper surface of the W film 18 in each gate electrode.

On the side of the gate electrode and on the HfO₂ film 12 in each region, an offset spacer 22 is formed. The offset spacer 22 is a film consisting mainly of SiO₂ or SiN, having a width of about 30 nm at the widest part. On the side of the offset spacer 22 and the HfO₂ film 12, a sidewall 24 is formed. The sidewall 24 is composed of SiN.

An extension 30, which is a diffused layer having a relatively low impurity concentration is formed outside the HfO₂ film 12 on the Si substrate 2 in each region, and a halo 32 is formed underneath the extension 30. The junction depth of the extension 30 in the substrate-depth direction is about 90 nm. Each halo 32 is formed so as to include the p-n junction of the extension 30 and wells 6 and 8. A source-drain region 34 having a relatively high impurity concentration is formed outside the sidewall 22 on the Si substrate 2. On the surface of the source-drain region 34, an NiSi layer 38 is formed.

Furthermore, an interlayer insulating film 40 is formed on the Si substrate so as to bury the gate electrode, the cap film 20, the offset spacer 22, the sidewall 24 and the like formed as described above. In the location passing through the interlayer insulating film 40 and reaching the NiSi layer 38, a contact plug 42 is formed. On the contact plug 42, a metal wiring 44 is formed.

In the semiconductor device 100 constituted as described above, the upper surface of the gate electrode formed in each region is protected with a cap film 20, and the side thereof is protected with the offset spacer 22 and the sidewall 24.

As described above, the gate electrode of the p-MIS 110 has a laminated structure consisting of an Ni film 14, a Ti film 16, and a W film 18; while the gate electrode of the n-MIS 120 has a laminated structure consisting of a Ti film 16 and a W film 18. Therefore, the gate electrode of the p-MIS 110 is thicker than the gate electrode of the n-MIS 120 by the thickness of the Ni film 14. In other words, the cross section shown in FIG. 1 is higher.

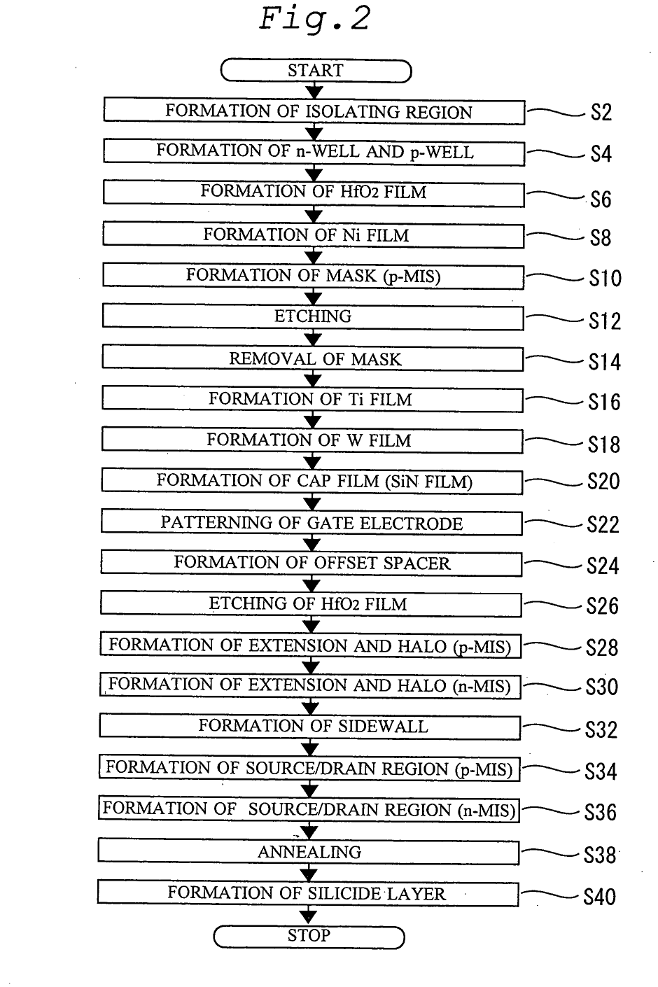

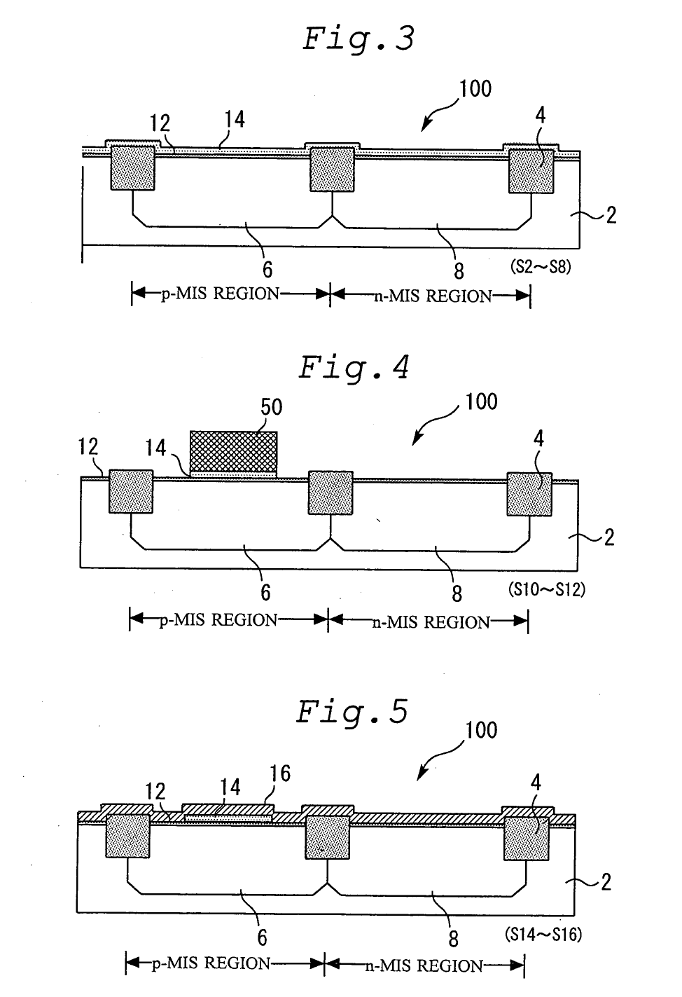

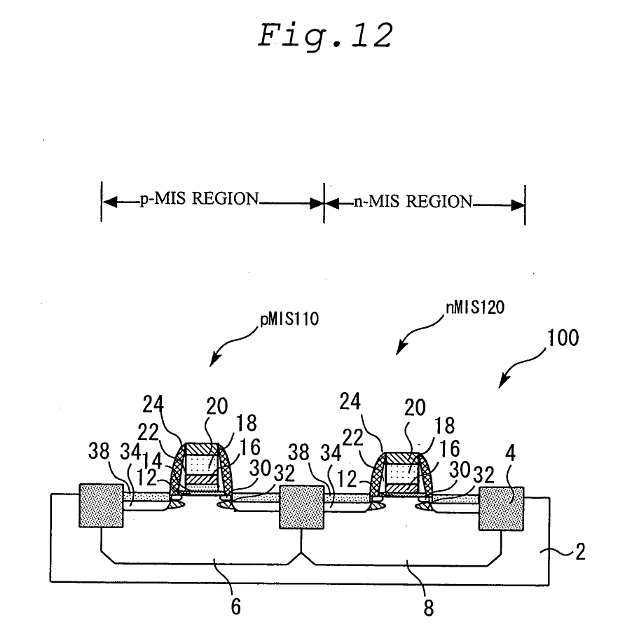

FIG. 2 is a flow diagram for illustrating the method for manufacturing a semiconductor device 100 according to the first embodiment of the present invention. FIGS. 3 to 12 are schematic sectional views for illustrating the states in each manufacturing step of the semiconductor device 100.

The method for manufacturing a semiconductor device 100 according to the first embodiment of the present invention will be described in detail, referring to FIGS. 1 to 11. In the description of the method for manufacturing a semiconductor device 100, the term “substrate” means a substrate to be processed including films or the like formed above the Si substrate 2 in each step.

First, as FIG. 3 illustrates, isolating regions 4 are formed on an Si substrate 2 (Step S2), for dividing the Si substrate 2 into a p-MIS region and an n-MIS region. Thereafter, an n-well 6 and a p-well 8 are formed on the p-MIS region and the n-MIS region, respectively (STEP S4). Then, an HfO₂ film 12 is formed on the Si substrate 2 (STEP S6), and an Ni film 14 is formed on the HfO₂ film 12 (Step S8). Here, the EOT of the HfO₂ film 12 is about 2.0 nm. The thickness of the Ni film 14 is about 5.0 nm to 10.0 nm.

Next, as FIG. 4 illustrates, a mask 50 is formed that coats at least the site to form the gate electrode of the p-MIS region using a photolithography method (STEP S10). Next, etching is performed using the mask 50 as the mask (STEP S12). Here, the etching method less damaging the HfO₂ film 12, such as wet etching, is used. Thereby, the Ni film 14 in the vicinity of the site to form the gate electrode of the n-MIS region is removed to expose the HfO₂ film 12. Thereafter, the mask 40 is removed (STEP S14).

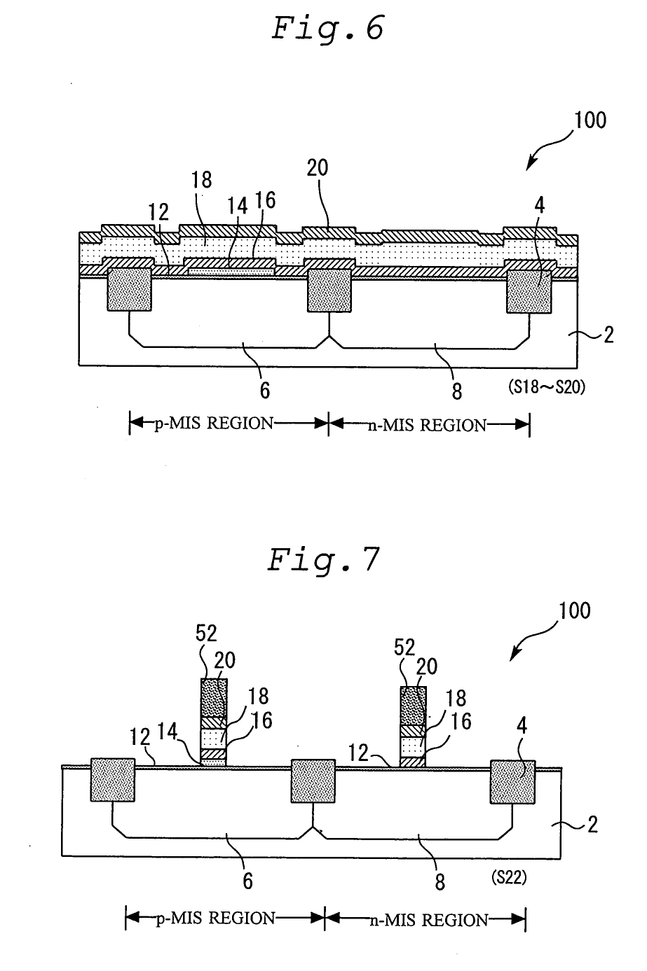

Next, as FIG. 5 illustrates, a Ti film 16 is formed on the entire surface of the substrate (STEP S16). The thickness of the Ti film 16 is about 5.0 nm to 10.0 nm. Next, as FIG. 6 shows, a W film 18 is formed on the Ti film 16 (STEP S18), and an SiN film as a cap film 20 is formed on the W film 18 (STEP S20). Here, the thickness of the W film 18 is about 40 to 50 nm.

Next, as FIG. 7 illustrates, patterning of a gate electrode is processed (STEP S22). Here, first, a resist mask 52 that coats site to form the gate electrode on the cap film 20 is formed in each region using photolithography. Using the resist mask 52 as the mask, the cap film 20, the W film 18, the Ti film 16, and the Ni film 14 are etched in this order. Thereafter, the resist mask 52 is removed. For this etching, an anisotropic etching, such as RIE (reactive ion etching) is used. Etching less damaging the HfO₂ film 12 or the Si substrate 2 is selected considering the etching selectivity of the HfO₂ film 12 or the Si substrate 2 to the material film for the gate electrode.

Thereby, a gate electrode is formed in each of the p-MIS region and n-MIS region. As described above, the gate electrode formed in the p-MIS region is thicker than the gate electrode formed in the n-MIS region by the thickness of the Ni film 14 (about 5.0 nm to 10.0 nm).

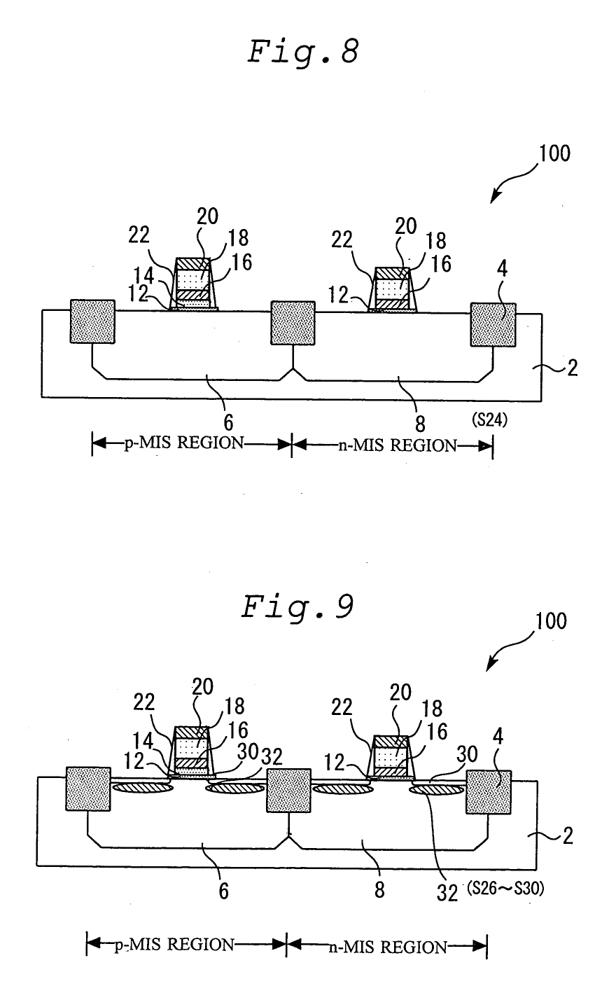

Next, as FIG. 8 illustrates, offset spacers 22 are formed (STEP S24). Here, after depositing an SiN film using an LPCVD (low pressure chemical vapor deposition) method, or an SiO₂ film using a PECVD (plasma enhanced chemical vapor deposition) method, the SiN (SiO₂) film is etched back so as to leave the SiN (SiO₂) film to form the offset spacers 22. The width of an offset spacer 22 is about 30 nm at the widest part in the lateral direction in FIG. 8). Since the gate electrode of the p-MIS is thicker than the gate electrode of the n-MIS by about 5.0 nm to 10.0 nm, the thickness of the offset spacer 22 in the p-MIS region. (in the vertical direction in FIG. 8) is generally formed to be thicker than the offset spacer 22 in the n-MIS region.

Here, the temperature when the SiO₂ film is formed using the PECVD method is about 400° C. or below in order to avoid the oxidation of the surface of each metal in the gate electrode.

Next, as FIG. 9 shows, the HfO₂ film 12 exposed to the surface outside the offset spacers 22 is removed by etching (STEP S26). Here, wet etching is used, and the etching selectivity of the offset spacers 22 to the HfO₂ film 12 is made sufficiently large so that the thickness of the offset spacers 22 is maintained at a desired thickness. In this wet etching, since the offset spacers 22 and the cap film 20 protect the gate electrode, the gate electrode is not damaged even if a chemical solution or gas that etches metal materials is used.

Next, an extension 30 and a halo 32 are formed in the p-MIS region (STEP S28). Here, a resist mask coating the n-MIS region is formed, and the ions of a p-type impurity are implanted into the Si substrate 2 using the resist mask, and the gate electrode and the offset spacer 22 in the p-MIS region as a mask. Thereby, the extension 30 is formed in the p-MIS region. Thereafter, the ions of an n-type impurity are implanted with a tilt angle to form the holo 32. The halo 32 is formed so as to include the p-n junction of the extension 30 and the n-well 6. Here, in the formation of the halo 32, since tilt ion implantation is performed, the ions have lateral momentum. Therefore, when a metal is exposed on the side of the gate electrode, the metal may be sputtered. However, since the offset spacer 22 protects the side of the gate electrode, the sputtering of the gate electrode by ions can be suppressed.

In particular, the angle of ion implantation is adjusted so as to satisfy the relationship of Equation (1):
Rp×sin θ≦W (1)
where Rp represents the projection range of ions, θ represents the incident angle of ions to the normal direction of the surface of the substrate 2, and W represents the width of the widest part of the offset spacer 22 in lateral direction in FIG. 9.

Thereby, the implantation of ions that have passed through the offset spacer 22 can also be suppressed.

Next, an extension 30 and a halo 32 are formed in the n-MIS region (STEP S30). Here, a resist mask coating the p-MIS region is formed, and the ions of an n-type impurity are implanted into the Si substrate 2 to form the extension 30, using the resist mask, and the gate electrode and the offset spacer 22 in the n-MIS region as a mask. Thereafter, the ions of an p-type impurity are implanted with a tilt angle to form the halo 32. The halo 32 is formed so as to include the p-n junction of the extension 30 and the p-well 8. The incident angle of ions to the normal direction of the surface of the Si substrate 2, θ, is determined from Equation (1) so that Rp×sin θ becomes the thickness W of the offset spacer 22 or less.

In general, the diffusion of a p-type impurity is faster than the diffusion of an n-type impurity. Therefore, projection range of ions in the impurity of the halo 32 in the p-MIS region (i.e., n-type impurity) requires to be larger range than that in the n-MIS region so as to form the diffusion layer of the same depth in each region. However, in the first embodiment, as described above, the gate electrode in the p-MIS region is thicker, and accordingly, the offset spacer 22 of the p-MIS region is generally thicker than the offset spacer 22 of the n-MIS region. In other words, the stopping power of the offset spacer 22 in the depth direction of the substratein the ion implantation of the halo 32 in the p-MIS region is higher than that in the n-MIS region. Therefore, even in the p-MIS region where the projection range of ions is larger, the increase in density of the halo 32 under the offset spacer 22 can be effectively suppressed.

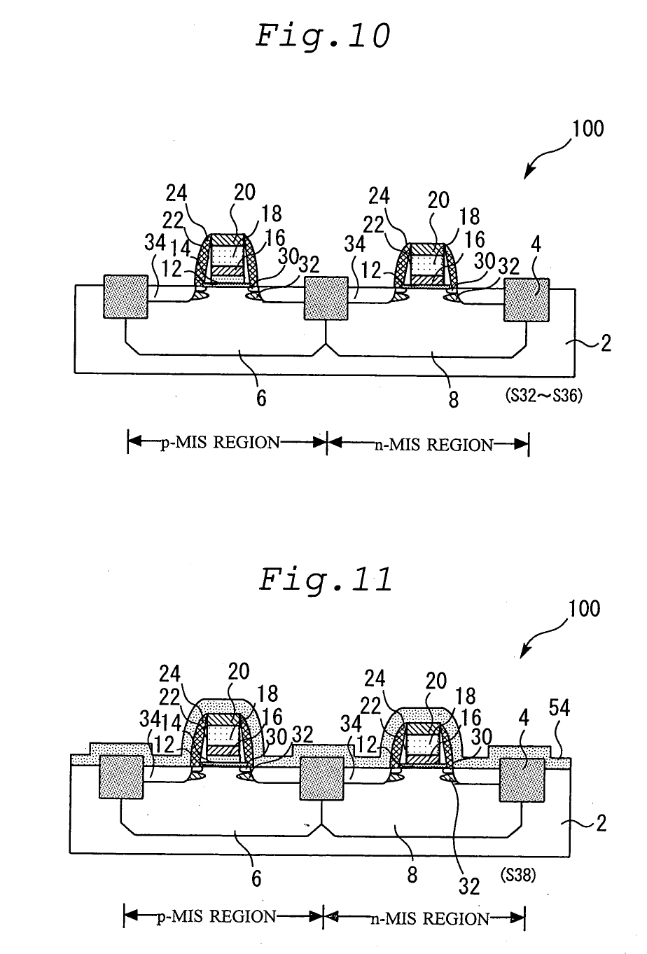

Next, As FIG. 10 illustrates, a sidewall 24 is formed on the sides of the offset spacer 22 and the HfO₂ film 12 in each region (STEP S32). Here, after depositing an SiN film using a CVD (chemical vapor deposition) method, the film is etched back so as to leave the SiN film only on the sides of the offset spacer 22 and the HfO₂ film 12 to form the sidewall 24.

Next, a source-drain region 34 is formed in the p-MIS region (STEP S34). Here, a resist mask to coat the n-MIS region is formed, and the ions of a p-type impurity are implanted using the resist mask, and the gate electrode, the offset spacer 22, and the sidewall 24 in the p-MIS region, as a mask. After ion implantation, the resist mask is removed. Thereafter, a source-drain region 34 is formed in the n-MIS region (STEP S36). Here, a resist mask to coat the p-MIS region is formed, and the ions of an n-type impurity are implanted using the resist mask, and the gate electrode, the offset spacer 22, and the sidewall 24 in the n-MIS region as a mask. After ion implantation, the resist mask is removed. After the ions of impurities are implanted, annealing for activating the impurities are performed (STEP S38). Here, annealing is performed at a temperature of about 1000° C. to 1050° C. for about 1 second.

Next, an NiSi layer 38 is formed on the source-drain region 34 of the Si substrate 2 (STEP S40). Here, as FIG. 11 illustrates, an Ni film 54 is formed on the entire surface of the substrate 2. Thereafter, heat treatment is performed at about 400° C. for about 30 seconds. Thereby, Si in the Si substrate 2 exposed on the surface of the source-drain region 34 reacts with Ni in the Ni film 54 to form the self-aligned NiSi layer 38 on the source-drain region 34. Thereafter, the Ni film 54 that has not reacted is selectively removed by wet etching using a mixed solution of sulfuric acid and hydrogen peroxide, a mixed solution of ammonia and hydrogen peroxide, or a mixed solution of ammonia, and hydrogen peroxide and water. In this case, since the cap film 20, the offset spacer 22, and the sidewall 24 also protect the gate electrode, the gate electrode is not damaged, such as dissolution in the chemical solution.

Thereafter, using the conventional techniques, an interlayer insulating film 40 is formed on the substrate 2, contact plugs 42 reaching the NiSi layer 38 are formed in the interlayer insulating film 40, and metal wirings 44 connected to the contact plugs 42 are formed on the interlayer insulating film 40.

As described above, a semiconductor device 100 as shown in FIG. 1 can be formed.

According to the first embodiment, a cap film 20 is formed on the surface of the gate electrode and an offset spacer 22 is formed on the side of the gate electrode in each region. Since the cap film 20 and the offset spacer 22 protect the gate electrode, no ions mix in the gate electrode during subsequence ion implantation for forming the extension 30, the halo 32, and the source-drain region 34. Therefore, the degradation of the metal gate can be suppressed in the subsequent steps, and a semiconductor device having excellent device characteristics can be formed. According to the first embodiment, the cap film 20 has been formed before forming-the gate electrode, and the offset spacer 22 is formed immediately after patterning the gate electrode. Therefore, the simultaneous etching of the gate electrode during etching of each film after forming the gate electrode can be prevented. Therefore, a minute semiconductor device having excellent device characteristics can be accurately manufactured.

Especially in the first embodiment, tilt ion implantation is performed for forming the halos 32. At this time, since ions have a momentum in the lateral direction, if metal is exposed on the side of the gate electrode, it is considered that the metal is sputtered to be deposited in the apparatus causing cross-contamination, or to be deposited on the substrate causing self-contamination. However, according to the first embodiment, since the offset spacer 22 has also protected the side of the gate electrode when ions are implanted, the sputtering of metals used in the gate electrode can be prevented. It is also considered that ions pass through the offset spacer and are implanted into the metals from the side of the gate electrode. However, according to the first embodiment, the angle of ion implantation is calculated considering the thickness of the offset spacer 22 when the halos 32 are formed using tilt implantation. Therefore, the mixing of ions that have passed through the offset spacer 22 can be suppressed in the formation of the hole 32.

Since the gate electrode of the p-MIS 110 is thicker than the gate electrode of the n-MIS 120, the thickness of the offset spacer 22 of the p-MIS 110 in the vertical direction to the substrate is generally formed to be thicker than the offset spacer 22 of the n-MIS 120. Thereby, the mask in the ion implantation for the halo 32 in the p-MIS region is thicker than the mask in the n-MIS region. Therefore, even in the p-MIS region where the projection range of ions is larger, the quantity of the impurity that overflows the offset spacer 22 used as the mask and is implanted into the substrate can be reduced, and the increase in density of the halo 32 under the offset spacer 22 can be effectively suppressed.

In the first embodiment, the case where a p-MIS 110 and an n-MIS 120 are formed on a substrate is described for the simplification of description. However, the present invention is not limited thereto, but can be applied to various cases, such as the case where only p-type or n-type transistors are formed, or the case where a plurality of p-type and n-type transistors are formed.

In the first embodiment, the case where an HfO₂ film 12 of an EOT of about 2 nm is used as a gate insulating film is described. However, in the present invention, the material and the thickness of the gate insulating film are not limited thereto. The gate insulating film may be a single-layer film selected from a group consisting of a high-k film, such as an HfO₂ film, an HfSiₓO_{y} film and an HfAlₓO_{y} film, an SiO₂ film, or a film formed by adding nitrogen to these films; or may be a laminated film containing at least one film selected from such a group. The thickness of the gate insulating film can be determined appropriately considering the gate length, the acceptable value of EOT, the acceptable value of leakage current and the like.

In the first embodiment, the gate electrode of a structure formed by laminating a plurality of metallic films is described. This is because the threshold voltage of the gate electrode must be lowered. However, when the threshold voltage is considered, the structure of the gate electrode is not limited thereto, but the structure may be formed of a single-layer metallic film, or may be formed by laminating a larger number of layers.

In the first embodiment, the case where an Ni film 14 is formed as the lowermost metallic film of the gate electrode in the p-MIS region is described. However, the lowermost metallic film is not limited thereto, but may select other materials having a work function close to the work function of p⁺-poly-Si in order to lower the threshold voltage of the p-MIS 110. The examples of such films include metallic films composed of at least one metal selected from a group consisting of Pd, Pt, Co, Rh, Ru, Cu, Ag, and Au, as well as the above-described Ni. The lowermost metallic film may also be a film composed of a nitride, silicide, carbide, oxide, or other compounds of at least one of metals selected from the metal group, as long as the compound has a work function close to the work function of p⁺-poly-Si, and has conductivity. For example, the oxide of Ru or Ir can be considered as the metal oxide. Furthermore, stoichiometric TiN, TaN, ZrN, HfN, NbN, and the like may also be used.

Here, the Ni film 14 is used for controlling the work function. Therefore, the thickness thereof can be about 1 to 2 nm; however, the present invention is not limited to this thickness range. The thickness thereof can be decided considering the film type of the metallic film, the required film thickness of the gate electrode, or the like.

For the gate electrode in the n-MIS region, the case where a Ti film 16 is formed on an Ni film 14 is described. However, in the present invention, the metallic film on the Ni film 14 is not limited thereto, but may select other materials having a work function close to the work function of n⁺-poly-Si in order to lower the threshold voltage of the n-MIS 120. The examples of metallic films substituting the Ti film 16 include metallic films composed of at least one metal selected from a group consisting of Zr, Hf, V, Nb, Ta, Cr, Mo, and W. The metallic film may also be a film composed of a nitride, silicide, carbide, oxide, or other compounds of at least one of metals selected from the metal group, as long as the compound has a work function close to the work function of n⁺-poly-Si, and has conductivity. However, the nitrides of Ti, Ta, Zr, Hf, or Nb are suitable for the materials for the gate electrode of the n-MIS, when the nitrogen content of these nitrides are lower than stoichiometry, but the content of N is low.

The Ti film 16 is adopted for controlling the work function. Therefore, the thickness of about 1 to 2 nm is sufficient; however, in the present invention, the thickness is not limited to this range. As described above, the thickness thereof can also be decided considering the film type of the metallic film, the required film thickness of the gate electrode, or the like.

In the first embodiment, the case where an Ni film 14 is formed in the p-MIS region, and thereafter, a Ti film 16 is formed, is described. However, in the present invention, the Ti film may be first formed, and the Ti film is left only in the n-MIS region, then the Ni film may be formed in both the p-MIS and n-MIS regions. Such an order can be determined considering the ease of processing and the reactivity of the metallic film, such as Ni and Ti films used for controlling the work function, in each of the p-MIS and n-MIS regions.

In order to decide which metallic film should be selected from a p-MIS and an n-MIS for controlling the work function, for example the following procedures can be used: First, the combination of metallic films suitable for the p-MIS and the n-MIS are selected. Then, from these combinations of metallic films, a metallic film that has the highest etching selectivity when the material of the gate insulating film is considered is first formed.

As the further specific combination of metallic films for controlling the work function of the gate electrode, for example, the use of TiN for the p-MIS, and the use of ZrN, WSi, and TaSiN for the n-MIS can be considered. In these cases, when the gate insulating film contains, for example, SiO₂ or HfO₂ as the major component, a TiN film is first formed, and the TiN film in the n-MIS region can be selectively removed using H₂O₂, a mixed solution of H₂O₂ and H₂SO₄, or a mixed solution of H₂O₂, NH₃ and H₂O.

As the metallic film formed on the Ti film 16 in the gate electrode in each region, a W film is used. However, the present invention is not limited to the W film 18, but the films of a compound of W, such as WSi₂, or the films of other metals, such as Mo, can also be used. The case where the thickness of the W film 18 is about 40 to 50 nm is described. This thickness is determined so as to lower the sheet resistance to 5 Ω/cm² or less, but the present invention is not limited to such thickness or resistance.

In the first embodiment, the case where the W film 18 is separately formed on the Ti film 16 is described. However, the present invention is not limited thereto. Here, although different metallic films, the Ti film 16 and the W film 18, are laminated, one metallic film may be used as the upper metallic film and the lower metallic film, if the metallic film selected as the lower metallic film (here, the Ti film 16) has a resistivity equal to or lower than the resistivity of the metallic film selected as the upper metallic film (here, the W film 18), and if it is suitable for the subsequent steps.

In the first embodiment, the case where the cap film 20 as a protective film is formed using SiN is described. However, the present invention is not limited thereto. The cap film 20 may be formed using any material that is not deteriorated by ion implantation, acts as a barrier against the oxidation of the metal in an oxidizing atmosphere, and is difficult to react with the underlying metal (W film 18 in the first embodiment) during the heating step for activation. Specifically, for example, an SiO₂ film, or a laminated film of an SiO₂ film and an SiN film can be considered in addition to the SiN film; however, other materials can also be used if the above-described conditions are satisfied. However, if SiO₂ is used, consideration to minimize the etching quantity of the SiO₂ film is required in the treatment using a solution containing HF in the cleaning step.

In the first embodiment, the case where the resist mask 42 is used in processing the gate is described. However, the present invention is not limited thereto. For example, only the cap film 20 may be etched using a resist mask, and then the resist mask may be removed. The underlying metal can be etched using the cap film 20 as the hard mask.

In the first embodiment, as the material film for the offset spacer 22, the case where an SiN film is formed using an LPCVD method, or an SiO₂ film is formed using a PECVD method is described. This is because the use of SiN film, which can be formed in a reducing `atmosphere, is preferable as the offset spacer 22 for preventing the oxidation of the metal. This is also because when the SiO₂ film is used, since it is formed in an oxidizing atmosphere, the process temperature for film forming must be controlled to about 400° C. or below, and the films can be formed at a relatively low temperature by the PECVD method. However, the present invention is not limited thereto, but other CVD methods may also be used considering the type of the film to be formed, or the oxidation of the metal during film formation. As the film-forming method, CVD methods, which excel in film coverage is more preferable than PVD (physical vapor deposition) method. Even if the process is performed in a reducing atmosphere as in the case where the SiN is formed using a CVD method, it is preferable to elevate the temperature in a non-oxidizing atmosphere so that the surface of the metal is not oxidized in the ramp up step before starting deposition.

In the first embodiment, the case where the width of the offset spacer 22 is 30 nm at the widest part is described. However, in the present invention, the width of the offset spacer 22 is not limited thereto. The width of the offset spacer 22 can be determined considering the junction depth of the extension and the like. For example, when the gate length if 100 nm, the typical overlapping length of the extension and the gate electrode is 30 nm or less in one side. When the junction depth (xj) of the extension in the depth direction of the substrate is 90 nm, the spreading of the junction in the lateral direction is empirically estimated to be about 70% thereof, that is about 60 nm. In this case, when the film thickness of the offset spacer 22 is 30 nm or more, the overlapping length can be suppressed to 30 nm or less in one side. The junction depth of the extension is selected to be an optimal value from the restrictions of sheet resistance, the off current of the transistor and the like. Therefore, although it may be different from the above-described value, in this case, the film thickness of the offset spacer 22 can also be determined considering the above-described relationship.

As described above, the incident angle θ in the ion implantation for forming the halo 32 is adjusted so that Rp×sin θ is smaller than the width of the offset spacer 22. however in the present invention, this relationship is not necessarily realized. However, in order to effectively suppress the mixing of ions into the gate electrode in ion implantation, it is more effective to determine each value considering the relationship between the incident angle θ, the projection range of ions Rp, and the width of the offset spacer 22 W.

In the first embodiment, the case where the portion of the HfO₂ film 12 exposed outside the offset spacer 22 is removed after the formation of the offset spacer 22 using etching is described. This is because if ion implantation is performed through a gate insulating film having uneven remaining film thickness, the depth of the diffused layer and the quantity of the impurity introduced into the Si substrate through the remaining insulating film, such as the HfO₂ film, become uneven in a shallow impurity-diffused layer. However, in the present invention, the removal of the HfO₂ film is not limited to the case where the HfO₂ film is separately removed by etching after the formation of the offset spacer 22. For example, the HfO₂ film may also be removed during the etch-back step in the formation of the offset spacer 22.

Even in the case where the HfO₂ film is removed by etch back, or in the case where it is removed by separate etching, the metals of the gate electrode have been coated by the offset spacer 22. Therefore, the damage of the metal gate electrode can be prevented, and also in the methods used when the HfO₂ film is removed, the options of the usable processes are widened.

In the first embodiment, the case where an Ni film 54 is formed on the substrate, and an NiSi layer 38 is formed on the surface of a source-drain region 34 is described. However, the present invention is not limited thereto. For example, in the case where the surface of the Ni film 54 is deteriorated during heat treatment for silicide forming when the Ni film 54 is formed, a highly heat-resistant film, such as a TiN film, may be formed in place of the Ni film 54. The silicide layer is not limited to the NiSi layer, but for example, a CoSi₂ layer or a TiSi₂ layer may be formed by siliciding Co or Ti. For example, when Ti is used, the forming temperature is about 700° C. Since the silicide layer is formed for lowering resistance, the formation of silicide layer is not necessarily required if the consideration for the reduction of resistance is not required.

Second Embodiment

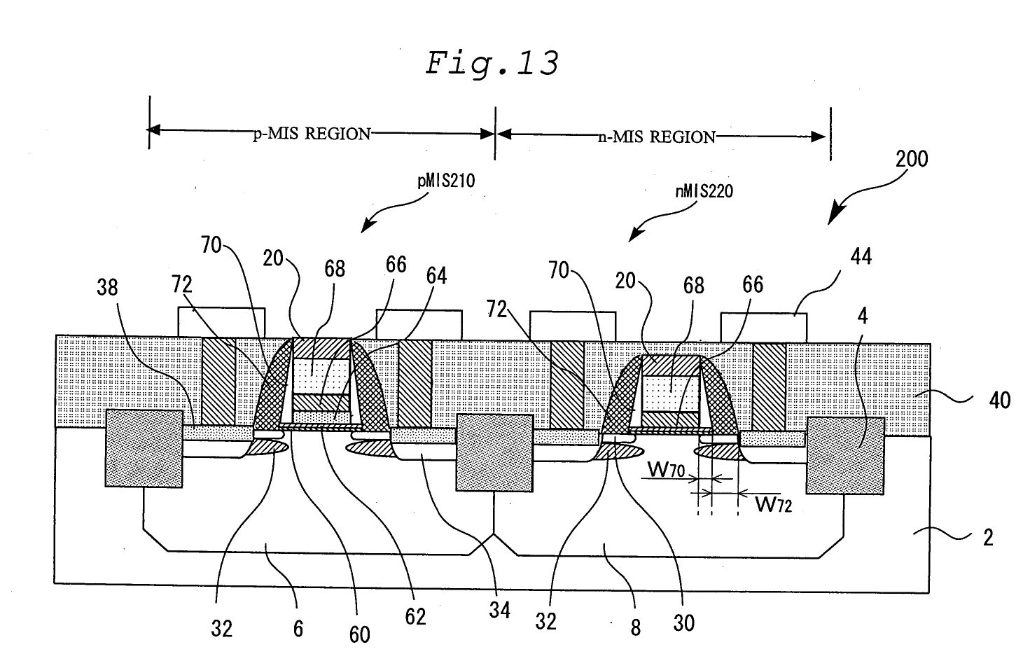

FIG. 13 is a schematic sectional view for illustrating a semiconductor device according to the second embodiment of the present invention.

The semiconductor device 200 shown in FIG. 13 is similar to the semiconductor device 100 in the first embodiment.

However, in the semiconductor device 200, a laminated film composed of an SiO₂ film 60 and an HfO₂ film 62 is used in both the p-MIS 210 and the n-MIS 220, in place of the HfO₂ film 12 used as the gate insulating film in the first embodiment.

In the p-MIS 210, a laminated film composed of a TiN film 64, a ZrN film 66, and a W film 68 is used as the gate electrode. In the n-MIS 220, a laminated film composed of a ZrN film 66 and a W film 68 is used as the gate electrode. In the same manner as the semiconductor device 100, a cap film 20 is formed on each gate electrode.

In also the second embodiment, an offset spacer 70 and a sidewall 72 are formed on the side of each gate electrode. The width of the widest part of the offset spacer 70. (i.e., the width of the closest to the substrate 2 in the cross-sectional direction) W₇₀ is about ⅓ to ½ of the width of the widest part of the sidewall 72, W₇₂. Specifically, while the gate length is about 50 nm, the width W₇₀ of the offset spacer 70 is about 10 nm, and the width W₇₂ of the sidewall 72 is about 25 nm.

Other structures are the same as in the first embodiment.

The method for manufacturing the semiconductor device 200 in the second embodiment is the same as in the first embodiment. However, the SiO₂ film is formed by thermal oxidation before forming the HfO₂ film 62 in Step S6. Thereafter, a TiN film is formed in place of the formation of the Ni film in Step S8. Then, in etching after the formation of the mask (Step S10), the TiN film in the n-MIS region is selectively removed using H₂O₂, a mixed solution of H₂O₂ and H₂SO₄, or a mixed solution of H₂O₂, NH₃ and H₂O. Thereafter, a ZrN film 64 is formed on the entire surface of the substrate so as to cover the TiN film 62 (Step S12). Furthermore, a W film 68 is formed (Step S14), and after forming the cap film 20, the gate is processed (Steps S16 and S18), then, the same steps as steps S20 to S40 in the first embodiment are carried out to form the semiconductor device 200.

In the second embodiment, as described above, a cap film 20 is formed on the surface, and an offset spacer 70 is formed on the side of the gate electrode in each region. Since the gate electrode is thus protected by the cap film 20 and the offset spacer 70, the damage of the metal gate during subsequent ion implantation can be suppressed, and a semiconductor device having favorable device characteristics can be obtained.

Also in the second embodiment, the case where the width of the widest part of the offset spacer 70 W₇₀ was 10 nm, and the width W₇₂ of the sidewall 72 was two to three times the width W₇₀ of the offset spacer 70, was described. Although these values are preferable for the typical gate length or junction depth of a semiconductor device, the present invention is not necessarily limited thereto. It is preferred that the width W₇₀ of the offset spacer 70 or the width W₇₂ of the sidewall 72 is decided considering the gate length or junction depth.

Specifically, for example, when the gate length is 100 nm, a typical overlapping length of the extension 30 and the gate electrode is about 30 nm or less in one side. When the junction depth (xj) of the extension 30 in the substrate depth direction is 90 nm, the spread in the lateral direction of the junction is empirically considered to be about 70% thereof, that is about 60 nm. Therefore, if the width W₇₀ of the offset spacer 70 is about 30 nm or more, the overlapping length can be suppressed to 30 nm or less for one side. Similarly, the overlapping length can be decided for the sidewall 72 considering the junction depth of the source-drain region 34. Specifically, when the junction depth is 150 nm, the spread in the lateral direction is about 70% thereof, which is about 105 nm. In order that-the location of the junction end does not enter in the channel side than the end portion of the gate electrode, the total width of the sidewall 72 and the offset spacer 70, W₇₀+W₇₂, is preferably 105 nm. Typically, as described above, the width W₇₂ of the sidewall 72 is considered to be two to three times the width W₇₀ of the offset spacer 70.

In the first and second embodiments, the cap film 20 corresponds to the protective film of the present invention; and the offset spacer 22 or 70 and the sidewall 24 or 72 correspond to the first and second sidewalls, respectively. In the embodiments, the extension 30 corresponds to the first impurity-diffused layer of the present invention; the source-drain region 34 corresponds to the second impurity-diffused layer of the present invention; and the halo 32 corresponds to the impurity diffusion preventing layer of the present invention.

In the embodiments, the p-MIS region and the n-MIS region correspond to the first and second regions of the present invention, respectively. In the embodiments, the p-type and the n-type correspond to the first and second conductivity types of the present invention, respectively. In the embodiments, the NiSi layer 38 corresponds to the metal silicide layer of the present invention.

In the embodiments, by carrying out Step S6, the insulating-film-forming step of the present invention is carried out. In the embodiments, by carrying out Steps S8 to S18, the metal-film-forming step of the present invention is carried out. For example, in the embodiments, by carrying out Step S20, the protective-film-forming step of the present invention is carried out. For example, in the embodiments, by carrying out Steps S22 and S24, the patterning step and the first-sidewall-forming step are carried out, respectively. For example, by carrying out Steps S28 to S30, the step for forming the first impurity-diffused layer of the present invention is carried out. In the embodiments, by carrying out Step S32, the step for forming the second sidewall of the present invention is carried out. For example, by carrying out Steps S34 to S36, the step for forming the second impurity-diffused layer of the present invention is carried out. For example, by carrying out Step S2, the step for forming the isolating region of the present invention is carried out.

For example, by carrying out Steps S8 to S12, the step for forming the first metallic film is carried out. For example, by carrying out step S16, the step for forming the second metallic film is carried out. For example, by carrying out Step S40, the step for forming the metal silicide layer of the present invention is carried out.

The features and the advantages of the present invention as described above may be summarized as follows.

According to one aspect of the present invention, a protective film is formed on the surface of the gate electrode using metallic films, and after a first sidewall has been formed, an impurity for forming a diffused layer is implanted into the sidewall. Therefore, the mixing of the impurity in the gate electrode in the impurity-implanting step can be prevented, and thereby, the deterioration of the gate electrode in the subsequent steps can be suppressed. In addition, since a first sidewall and a second sidewall are formed on the side of the gate electrode, the metals of the gate electrode are protected from etching from the side in the cleaning step or the like. Therefore, according to the present invention, a semiconductor device having excellent device characteristics can be obtained.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2003-358092, filed on Oct. 17, 2003 including specification, claims, drawings and summary, on which the Convention priority of the present application is based, are incorporated herein by reference in its entirety.

1. A semiconductor device comprising:
a substrate having a surface;
an isolating region dividing said substrate into a first region and a second region;
a first transistor of a first conductivity type located in said first region; and
a second transistor of a second conductivity type located in said second region, wherein each of said first transistor and said second transistor comprises:
a gate insulating film on said substrate;
a gate electrode including a metallic material on said gate insulating film;
a protective film coating said gate electrode;
a first sidewall coating sides of said gate electrode;
first impurity-diffused regions spaced apart from each other and on both sides of said first sidewall proximate the surface of said substrate;
a second sidewall coating at said first sidewall; and
second impurity-diffused regions spaced apart from each other and on both sides of said second sidewall, proximate the surface of said substrate, wherein said gate electrodes of said first and second transistors have a laminated structure including a plurality of metallic films, and said gate electrode of said first transistor includes an additional metallic film as a lowermost layer not present in the gate electrode of said second transistor.

2. The semiconductor device according to claim 1, wherein one of said electrodes of said first transistor or said second transistors includes a metallic film of at least one metal selected from the group consisting of Ni, Pd, Pt, Co, Rh, Ru, Cu, Ag, and Au and a silicide, or a carbide of at least one of these metals.

3. The semiconductor device according to claim 1, wherein one of said gate electrodes of said first transistor or said second transistor includes a metallic film of at least one metal selected from the group consisting of Ti, Zr, Hf, V, Nb, Ta, Cr, Mo, and W and a nitride, a silicide, or a carbide of at least one of these metals.

4. The semiconductor device according to claim 1, further comprising metal-silicide layers on said second impurity-diffused regions of said substrate.

5. The semiconductor device according to claim 1, wherein said gate electrode of said first transistor has a different height from the gate electrode of said second transistor, relative to the surface of said substrate.

6. The semiconductor device according to claim 1, wherein said second sidewall has a maximum width about two to three times the maximum width of said first sidewall.

7. The semiconductor device according to claim 1, wherein said gate insulating film is a single-layer film composed of a film selected from the group consisting of an SiO₂ film, an HfO₂ film, an HfAlₓO_{y} film, an HfSiₓO_{y} film, or one of these films to which nitrogen is added; or a laminated film including at least one film selected from this group.

8. A method for manufacturing a semiconductor device comprising:
forming an isolating region for dividing a substrate into a first region and a second region;
forming a gate insulating film in said first region and said second region;
forming a first metallic film on said gate insulating film in one of said first region and said second region;
forming a second metallic film on each of said first region and said second region;
forming a protective film on said second metallic film in said first region and said second region;
patterning said protective film, said first metallic film, and said second metallic film to form a gate electrode in each of said first region and said second region;
forming a first sidewall on each of gate electrodes in said first region and said second region;
implanting ions producing a first conductivity type into said first region using said gate electrode and said first sidewall as masks, and implanting ions producing a second conductivity type, opposite the first conductivity type, into said second region using said gate electrode and said first sidewall as masks, to form a first impurity-diffused region in each of said first and second regions;
forming an impurity diffusion preventing layer, including an interface of said first impurity-diffused region, by implanting ions producing the second conductivity type into said first region, using said gate electrode and said first sidewall as masks;
forming an impurity diffusion preventing layer, including an interface of said first impurity-diffused region, by implanting ions producing the first conductivity type into said second region, using said gate electrode and said first sidewall as masks
forming a second sidewall on each side of said first sidewall;
implanting ions producing the first conductivity type into said first region using said gate electrode and said first and second sidewalls as masks; and
implanting ions producing the second conductivity type into said second region using said gate electrode and said first and second sidewalls as masks, to form a second impurity-diffused region in each of said first and second regions.

9. The method for manufacturing a semiconductor device according to claim 8, wherein said impurity diffusion preventing layer is formed by oblique ion implantation, and
Rp×sin θ≦W is satisfied,
where Rp represents the projection range of ion implantation, θ represents the incident angle of ions relative to the normal to said substrate, and W represents maximum width of said first sidewall when ions are implanted in forming said impurity diffusion preventing layer.

10. The method for manufacturing a semiconductor device according to claim 8, wherein one of said first metallic film and said second metallic film is a metallic film including at least one metal selected from the group consisting of Ni, Pd, Pt, Co, Rh, Ru, Cu, Ag, and Au and a film composed of a silicide or a carbide of at least one of these metals.

11. The method for manufacturing a semiconductor device according to claim 8, wherein one of said first metallic film and said second metallic film is a metallic film including at least one metal selected from the group consisting of Ti, Zr, Hf, V, Nb, Ta, Cr, Mo, and W, and a film composed of a nitride, a silicide, or a carbide of at least one of these metals.

12. The method for manufacturing a semiconductor device according to claim 8, further comprising forming a metal silicide layer on each of said second impurity-diffused regions.

13. The method for manufacturing a semiconductor device according to claim 8, wherein the maximum width of said second sidewall is about two to three times the maximum width said first sidewall.

14. The method for manufacturing a semiconductor device according to claim 8, wherein forming said gate insulating film includes forming a single-layer film composed of a film selected from the group consisting of an SiO₂ film, an HfO₂ film, an HfAlₓO_{y} film, an HfSiₓO film, or one of these films to which nitrogen is added; or a laminated film including at least one film selected from this group.
